(19) United States
(12) Patent Application Publication
(10) Pub. No.: US 2025/0301606 A1
(43) Pub. Date: Sep. 25, 2025

(54) PASSIVE LIQUID RECYCLE DEVICE

(71) Applicant: WE SOLUTIONS TECHNOLOGY CO., LTD, Taoyuan City (TW)

(72) Inventors: CHUNG-PENG HUANG, Taoyuan City (TW); FANG-YI LIN, Taoyuan City (TW); KUAN-LIN CHEN, Taoyuan City (TW); CHUN-CHING KUO, Taoyuan City (TW); CHUNG-EN LEE, Taoyuan City (TW)

(73) Assignee: WE SOLUTIONS TECHNOLOGY CO., LTD, Taoyuan City (TW)

(21) Appl. No.: 18/788,175

(22) Filed: Jul. 30, 2024

(30) Foreign Application Priority Data
Mar. 25, 2024 (TW) 113111043

(51) Int. Cl. H05K 7/20

(52) U.S. Cl. CPC H05K 7/20381; H05K 7/203; H05K 7/20327

(57) ABSTRACT

A passive liquid recycle device for solving an issue of inappropriate pressure regulation often occurring in a conventional two-phase immersion cooling device. The passive liquid recycle device is adapted to be in communication with a two-phase immersion cooling device, and includes a housing and at least a bag, accommodated in a volume variable manner in the housing. The bag being higher than the two-phase immersion cooling device and capable of passively receiving a gaseous coolant from the two-phase immersion cooling device and accordingly expanding, and contracting after the gaseous coolant condenses into a liquid coolant and returns to the two-phase immersion cooling device.

### CROSS-REFERENCE TO RELATED APPLICATION

This non-provisional application claims priority under 35 U.S.C. § 119(a) on Patent Application No(s). 113111043 filed in Taiwan, R.O.C. on Mar. 25, 2024, the entire contents of which are hereby incorporated by reference.

### BACKGROUND OF THE INVENTION

### 1. Field of the Invention

The present disclosure relates to a supporting apparatus for a heat dissipation device, and in particular to a passive liquid recycle device suitable for a two-phase immersion cooling device.

### 2. Description of the Related Art

Accompanied with rapid increases in power and heat flux densities of heating components of electronic elements related to computing in computers, immersion cooling is currently one of the high-performance techniques to quickly reduce the amount of heat generated by electronic computing elements.

In general, a conventional two-phase immersion cooling device substantially includes a sealed chamber and a condensation module. The sealed chamber accommodates therein a liquid coolant (for example, perfluoro-ketone, having a boiling point of approximately 50° C.), and an electronic computing element is immersed in the liquid coolant. The condensation module is disposed at an upper position inside the sealed chamber. Accordingly, when an operating temperature of the electronic computing element rises, the liquid coolant around the electronic computing element absorbs heat, boils, and transforms into a gaseous state. The gaseous coolant ascends, and condenses back into a liquid state once coming into contact with the condensation module at a relatively low temperature, and drips back to the space below. Thus, an effect of coolant circulation for heat dissipation is achieved without involving additional resources or pump power.

### BRIEF SUMMARY OF THE INVENTION

However, during an operation of the above conventional two-phase immersion cooling device, if the operating temperature of the electronic computing element rises rapidly within a short period of time, a large amount of liquid coolant also rapidly vaporizes to generate a large amount of gaseous coolant. However, the condensation module is unable to immediately change such large amount of gaseous coolant back into a liquid state. In addition, the space of the sealed chamber is quite limited. Thus, in the event of a large amount of gaseous coolant generated within an extremely short period of time in the conventional two-phase immersion cooling device, a pressure inside the sealed chamber gets overly large, hence affecting the structure of the sealed chamber or even causing deformation. As a result, the gaseous coolant under the high pressure leaks through gaps of the sealed chamber to the outside, causing issues of environmental safety as well as difficulties in cost reduction due to the loss of the costly coolant.

In view of the above, the present disclosure provides a passive liquid recycle device, which can be in communication with a two-phase immersion cooling device and passively receive excessive gaseous coolant from a sealed chamber of the two-phase immersion cooling device, so as to prevent an overly large pressure inside the sealed chamber. Moreover, the gaseous coolant that flowed into the passive liquid recycle device can flow back inside the sealed chamber once condensed back into a liquid state.

The directional or similar terms used throughout the present disclosure, for example, “front”, “back/rear”, “left”, “right”, “up/upper/top”, “down/lower/bottom”, “in/inner”, “out/outer”, and “side surface”, are primarily provided with reference to the directions of the accompanying drawings. These directional or similar terms are intended to assist in describing and better understanding various embodiments of the present disclosure and are not to be construed as limitations to the present disclosure.

The articles “a/an” and “one” used for the elements and components described throughout the present disclosure are merely for the ease of use and for providing common meanings of the scope of the present disclosure, and should be interpreted as “one” or “at least one” in the present disclosure. Moreover, the concept of a singular form also includes cases of plural forms, unless otherwise specified.

Similar terms including “join”, “combine”, “couple”, or “assemble” used throughout the present disclosure primarily include forms which can be separated without sabotaging the components or contain inseparable components once connected, and can be selected by a person skilled in the art according to materials or assembly requirements of the components to be connected.

To achieve the above and other objects, the present disclosure provides a passive liquid recycle device, adapted to be in communication with a two-phase immersion cooling device, and including: a housing; and at least a bag, accommodated in a volume variable manner in the housing, the bag being higher than the two-phase immersion cooling device and capable of passively receiving a gaseous coolant from the two-phase immersion cooling device and accordingly expanding, and contracting after the gaseous coolant condenses into a liquid coolant and returns to the two-phase immersion cooling device.

The passive liquid recycle device of the present invention can further include a communication pipe group, and can be in communication with the two-phase immersion cooling device via the communication pipe group.

In the passive liquid recycle device of the present invention, the communication pipe group has an outer pipe and a guide pipe. The outer pipe can be in communication with an interior of the sealed chamber of the two-phase immersion cooling device, and the guide pipe can be in communication with the outer pipe and an interior of the bag.

In the passive liquid recycle device of the present invention, a plurality of bags are provided, and the interiors of the plurality of bags can all be in communication with the guide pipe.

In the passive liquid recycle device of the present invention, the guide pipe can be obliquely disposed, and a position thereof in communication with the outer pipe can be lower than a position thereof in communication with the bag.

In the passive liquid recycle device of the present invention, the guide pipe can be located within the housing, and the outer pipe is at least partially located outside the housing.

In the passive liquid recycle device of the present invention, the housing has therein at least one first hanging portion, and the bag can have at least one second hanging portion, wherein the second hanging portion is detachably connected to the corresponding first hanging portion.

In the passive liquid recycle device of the present invention, the first hanging portion can be disposed on an inner side of a top surface of the housing, and the second hanging portion can be disposed on a top end of the bag.

In the passive liquid recycle device of the present invention, the housing can have a frame base and a plurality of door panels, wherein the plurality of door panels are openably coupled on different sides of the frame base.

In the passive liquid recycle device of the present invention, the housing can have at least one pressure balance opening.

Accordingly, the passive liquid recycle device of the present disclosure can be in communication with a sealed chamber of a two-phase immersion cooling device and passively receive an excessive gaseous coolant from the sealed chamber, so as to prevent an overly large pressure inside the sealed chamber. Moreover, the gaseous coolant flowed into the passive liquid recycle device can flow back inside the sealed chamber once condensed back into a liquid state. Thus, the passive liquid recycle device is capable of effectively preventing damage of the two-phase immersion cooling device caused as a result of an overly large internal pressure so as to prolong the durability and reduce maintenance costs of the two-phase immersion cooling device, further achieving effects of preventing leakage of the gaseous coolant, improving operational environment safety, enhancing a recycle rate of the coolant, and thus reducing cooling costs. Moreover, the functions of pressure distribution and recycle of the coolant can be implemented without involving operations of an additional suction device or additional energy. Thus, the passive liquid recycle device also features low manufacturing costs, almost no operation costs or consumables, and low maintenance and repair costs. In addition, since the bag that expands and contracts is disposed in the housing with a fixed volume, there are no moving components with large volume changes around the two-phase immersion cooling device in operation, hence promoting operating efficiency as well as safety of operators.

### BRIEF DESCRIPTION OF THE DRAWINGS

FIG. 1 is a schematic diagram of a passive liquid recycle device in communication with a two-phase immersion cooling device according to an embodiment of the present disclosure.

FIG. 2 is an exploded perspective schematic diagram of the structure of a

passive liquid recycle device according to an embodiment of the present disclosure.

FIG. 3 is a perspective schematic diagram of the structure of a bag and a communication pipe group of a passive liquid recycle device according to an embodiment of the disclosure.

FIG. 4 is a side sectional schematic diagram of the structure of a passive

liquid recycle device according to an embodiment of the present disclosure.

FIG. 5 is a side sectional schematic diagram of the structure of a passive liquid recycle device from another perspective according to an embodiment of the present disclosure.

FIG. 6 is a partial perspective schematic diagram of the structure of a passive liquid recycle device according to an embodiment of the present disclosure.

### DETAILED DESCRIPTION OF THE INVENTION

To facilitate understanding of the object, characteristics, and effects of the present disclosure, embodiments together with the attached drawings for the detailed description of the present disclosure are provided below.

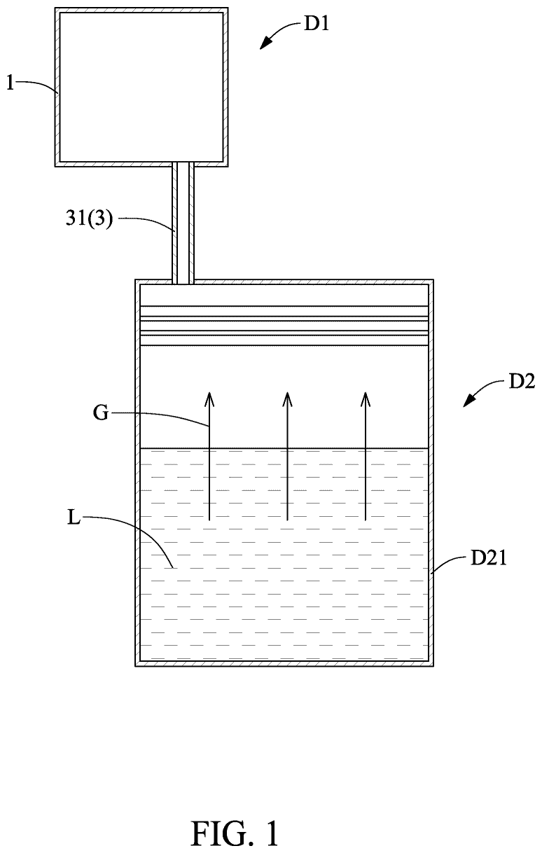

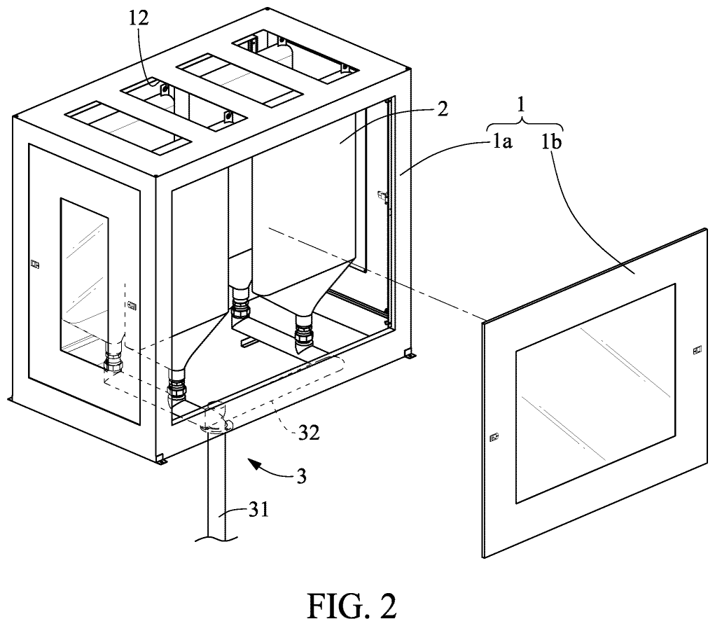

Referring to FIG. 1 and FIG. 2 showing a passive liquid recycle device D1 according to an embodiment of the present disclosure. The passive liquid recycle device D1 is adapted to be in communication with a two-phase immersion cooling device D2, wherein a means of the communication is not specifically defined. The passive liquid recycle device D1 includes a housing 1 and at least one bag 2. The bag 2 is accommodated in a volume variable manner in the housing 1. The bag 2 is higher than the two-phase immersion cooling device D2, and is capable of passively receiving a gaseous coolant G from the two-phase immersion cooling device D2 and accordingly expanding, and contracting after the gaseous coolant G condenses into a liquid coolant L and returns to the two-phase immersion cooling device D2.

Accordingly, when a pressure inside a sealed chamber D21 of the two-phase immersion cooling device D2 is overly large, the excessive gaseous coolant G within the sealed chamber D21 can directly flow into the passive liquid recycle device D1 and be passively received by the passive liquid recycle device D1 to further cause the bag 2 to expand, thereby effectively preventing deformation caused by an overly large pressure inside the sealed chamber D21 from causing leakage of the gaseous coolant G. Moreover, the gaseous coolant G flowed into the bag 2 can be condensed back into the liquid coolant L and then again flow back to an interior of the sealed chamber D21 and recycle for repeated use. Thus, the passive liquid recycle device D1 of this embodiment is capable of effectively preventing damage of the two-phase immersion cooling device D2 caused as a result of an overly large internal pressure so as to prolong the durability and reduce maintenance costs of the two-phase immersion cooling device D2, further achieving effects of preventing leakage of the gaseous coolant G and improving operational environment safety, while also enhancing a recycle rate of the costly coolant and thus reducing cooling costs.

In particular, the above functions of pressure distribution and recycling of the coolant can be implemented without involving operations of an additional suction device or additional energy. Moreover, the passive liquid recycle device D1 has a simple structure that can be easily manufactured and assembled, and can be operated with less consumables and does not require frequent maintenance and repair, offering high practicability.

Alternatively, the passive liquid recycle device D1 is provided with the housing 1, and the bag 2 that expands and contracts is disposed within the housing 1 having a fixed volume. Thus, in addition to providing the bag 2 with protection and dust-resistance by the housing 1, there are no moving components with large volume changes around the two-phase immersion cooling device D2 in operation. Thus, it is visually calmer, and operators around the two-phase immersion cooling device D2 are prevented from a sense of irritation, hence promoting operating efficiency as well as safety of operators.

Referring to FIG. 1 to FIG. 3, in addition to the embodiments above, in an embodiment of the present disclosure, the passive liquid recycle device D1 can further include a communication pipe group 3, and can be in communication with the two-phase immersion cooling device D2 via the communication pipe group 3. Thus, the ease of communication of the passive liquid recycle device D1 with the two-phase immersion cooling device D2 can be enhanced, and it can be ensured that both of the gaseous coolant G flowing into the passive liquid recycle device D1 and the liquid coolant L flowing into the two-phase immersion cooling device D2 are kept with good fluidity.

In an embodiment of the present disclosure, the communication pipe group 3 has an outer pipe 31 and a guide pipe 32. The outer pipe 31 can be in communication with an interior of the sealed chamber D21 of the two-phase immersion cooling device D2, and the guide pipe 32 can be in communication with the outer pipe 31 and an interior of the bag 2. Thus, the communication pipe group 3 can help in reducing manufacturing costs and enhancing the ease of assembly by a simple structure.

In an embodiment of the present disclosure, a plurality of bags 2 are provided, and the interiors of the plurality of bags 2 can all be commonly in communication with the guide pipe 32. Thus, accompanied with the configuration of the pipes, the gaseous coolant G from the interior of the sealed chamber 21 can flow to another bag 2 through the guide pipe 32 while causing one of the bags 2 to expand, hence quickly alleviating the high pressure inside the sealed chamber D21, providing effects of enhanced pressure reduction efficiency. For example, four bags 2 can be disposed in the housing 1 in an embodiment, the four bags 2 are arranged in pairs in two rows, the guide pipe 32 can be selectively implemented by a U-shaped pipe, and two parallel portions of the guide pipe 32 are in communication with two bags 2, such that the interiors of the four bags 2 are all commonly in communication with the guide pipe 32. However, the form of the guide pipe 32 of the present disclosure is not specifically defined.

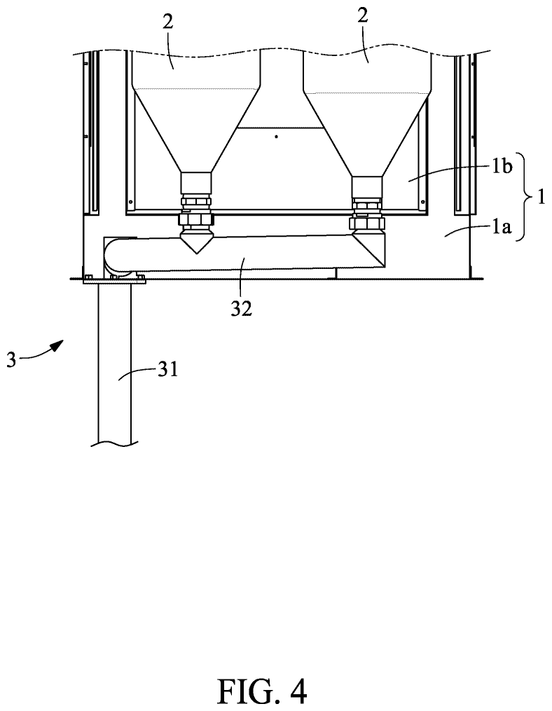

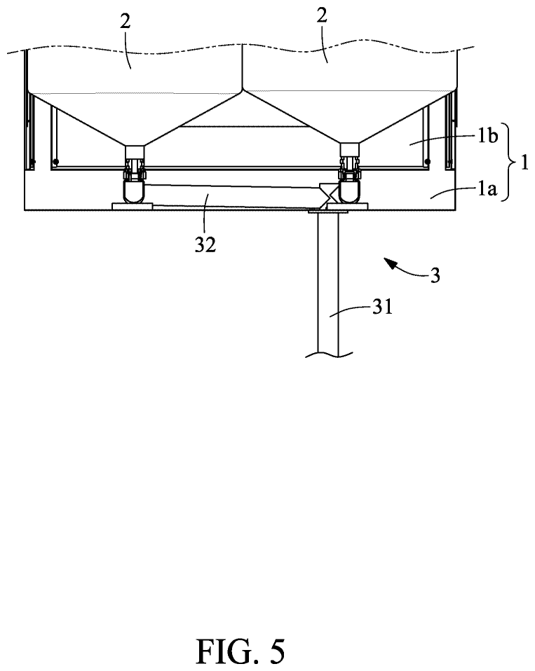

Referring to FIG. 1, FIG. 4, and FIG. 5, in an embodiment of the present disclosure, the guide pipe 32 can be obliquely disposed, and a position thereof in communication with the outer pipe 31 is lower than a position thereof in communication with the bag 2. Thus, the gaseous coolant G input into the bag 2, after condensed into the liquid coolant L, can more smoothly pass through the outer pipe 31 along the inclination of the guide pipe 32 to return to the interior of the sealed chamber D21, hence reducing a residual amount of the liquid coolant L in the communication pipe group 3 and achieving an effect of enhancing a recycle rate of the liquid coolant L.

Referring to FIG. 1 and FIG. 2, in an embodiment of the present disclosure, the guide pipe 32 can be located within the housing 1, and the outer pipe 31 can be at least partially located outside the housing 1. Thus, in the communication pipe group 3, most of the pipes can be commonly accommodated within the housing 1 along with the bag(s) 2 in contact and be together protected by the housing 1, preventing accidental collisions that can cause deformation or damage to the pipes. In terms of appearance, the passive liquid recycle device D1 and the two-phase immersion cooling device D2 are only connected by a simple pipe (a portion of the outer pipe 31 exposed outside the housing 1) in between, so that an operational environment can appear neat and tidy. Moreover, the pipes are kept less likely to engage with operators or other objects to further provide better safety.

It should be noted that, although the vertically arranged outer pipe 31 is in communication with the passive liquid recycle device D1 and the two-phase immersion cooling device D2 in the drawings of embodiments, the present disclosure is not limited thereto. In some embodiments, the outer pipe 31 can also be obliquely arranged, and a length of the outer pipe 31 and a height of the passive liquid recycle device D1 with respect to the two-phase immersion cooling device D2 can also be modified according to factors such as site planning; the present disclosure is not limited to the forms shown in the drawings.

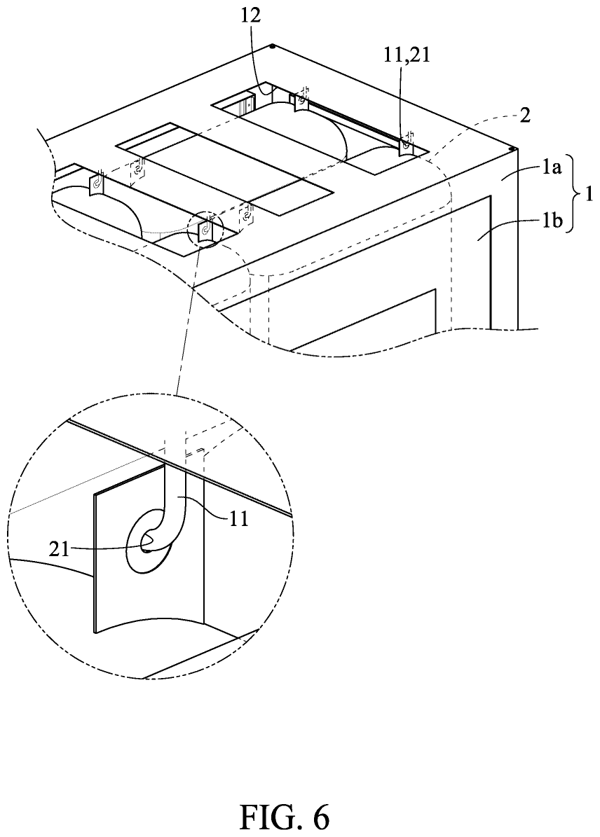

Referring to FIG. 1 and FIG. 6, in addition to the embodiments above, in an embodiment of the present disclosure, the housing 1 has therein at least one first hanging portion 11, and the bag 2 can have at least one second hanging portion 21, wherein the second hanging portion 21 is detachably connected to the corresponding first hanging portion 11. Thus, the bag 2 can be kept in a state of being hung within the housing 1, and the second hanging portion 21 and the first hanging portion 11 jointly limit the bag 2 from collapsing and tilting within the housing 1, preventing the bag 2 in a non-expanded state from collapsing and tilting that can cause difficulties in inputting the gaseous coolant G, as well as preventing the bag 2 in an expanded state from collapsing and tilting that can cause difficulties in outputting the liquid coolant L and difficulties in successfully returning the liquid coolant L back to the interior of the sealed chamber D21.

The first hanging portion 11 can be selectively disposed on an inner side of a top surface of the housing 1, and the second hanging portion 21 can be selectively disposed on a top end of the bag 2, so as to achieve preferred effects of hanging the bag 2. The present disclosure does not specifically define the forms of the first hanging portion 11 and the second hanging portion 12. For example but not limited to, the first hanging portion 11 and the second hanging portion 21 corresponding to each other can be a loop and a hook, a male fastener and a female fastener, hook-and-loop fasteners, adhesive tapes attached to an inner wall of the housing 1 or magnetic fixing means, which are all considered equivalent structures of the present disclosure.

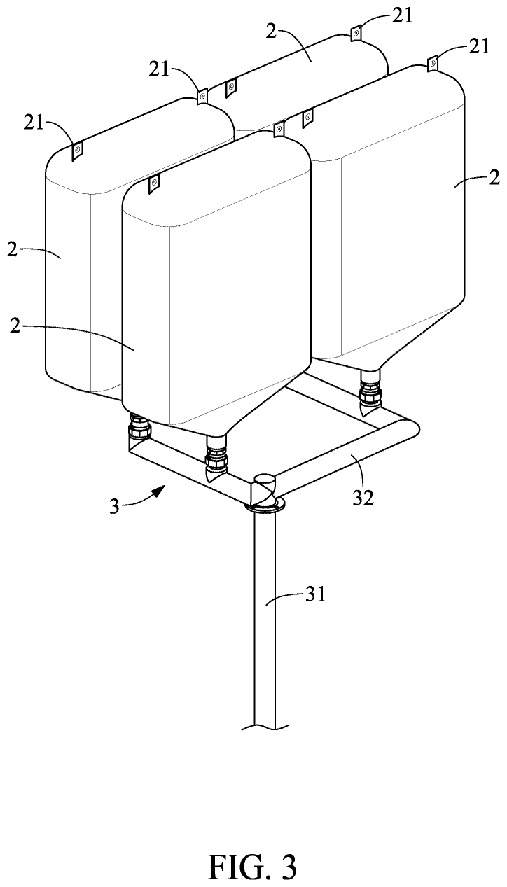

On the other hand, referring to FIG. 3, in an embodiment of the present disclosure, the bag 2 can appear substantially a cuboid when it completely expands, and have a bottom portion thereof formed as a gradually tapered shape. Thus, the bag 2 can expand into an expected three-dimensional form to prevent from inappropriately pressing against the housing 1 and hence from causing damage of the bag 2 or deformation of the housing 1. Moreover, the shape of the bottom portion of the bag 2 can further enhance the smoothness of outputting the liquid coolant L and reducing a residual amount of the liquid coolant L. In addition, each of the bags 2 of some embodiments can be provided with a plurality of second hanging portions 21 at the top end, such that the bag 2 can be easily fully spread into a three-dimensional shape after expanding and be kept at a predetermined position, thus preventing adjacent bags 2 from rubbing against each other or overlapping each other that can obstruct the process of expansion.

Referring to FIG. 2, in addition to the embodiments above, in an embodiment of the present disclosure, the housing 1 can have a frame base 1a and a plurality of door panels 1b. The plurality of door panels 1b can be openably coupled on different sides of the frame base 1a, for example, front, back, left, right, and/or top sides of the frame base 1a. Thus, the plurality of door panels 1b enable the housing 1 to open in multiple directions, achieving an effect of enhanced ease of maintenance.

In an embodiment of the present disclosure, the door panel 1b can be made of a transparent material, for example, glass or acrylic, or a see-through window can be disposed in a non-transparent door frame. Thus, conditions within the housing 1 can be easily observed from the outside of the housing 1, achieving an effect of enhanced ease of maintenance or observing whether the bag 2 is functioning well.

In addition to the embodiments above, in an embodiment of the present disclosure, the housing 1 can have at least one pressure balance opening 12. Thus, once the bag 2 expands, air originally within the housing 1 can be discharged from the pressure balance opening 12, so as to balance pressures inside and outside the housing 1. In some embodiments, the pressure balance opening 12 can be selectively disposed on a top surface of the frame base 1a. In other embodiments, the pressure balance opening 12 can also be disposed at other positions of the frame base 1a, or even be disposed at the door panel 1b; the present disclosure is not limited to the examples above.

The present invention is described by way of the preferred embodiments above. A person skilled in the art should understand that, these embodiments are merely for describing the present invention and are not to be construed as limitations to the scope of the present invention. It should be noted that all equivalent changes, replacements and substitutions made to the embodiments are encompassed within the scope of the present invention. Therefore, the legal protection of the present invention should be defined by the appended claims.

What is claimed is:

1. A passive liquid recycle device, adapted to be in communication with a two-phase immersion cooling device, the passive liquid recycle device comprising:
a housing; and
at least one bag, accommodated in a volume variable manner in the housing, the bag being higher than the two-phase immersion cooling device and capable of passively receiving a gaseous coolant from the two-phase immersion cooling device and accordingly expanding, and contracting after the gaseous coolant condenses into a liquid coolant and returns to the two-phase immersion cooling device.

2. The passive liquid recycle device of claim 1, further comprising a communication pipe group, wherein the passive liquid recycle device is in communication with the two-phase immersion cooling device via the communication pipe group.

3. The passive liquid recycle device of claim 2, wherein the communication pipe group has an outer pipe and a guide pipe, the outer pipe is in communication with an interior of a sealed chamber of the two-phase immersion cooling device, and the guide pipe is in communication with the outer pipe and an interior of the bag.

4. The passive liquid recycle device of claim 3, wherein a plurality of bags are provided, and the interiors of the plurality of bags are all in communication with the guide pipe.

5. The passive liquid recycle device of claim 3, wherein the guide pipe is obliquely disposed, and a position thereof in communication with the outer pipe is lower than a position thereof in communication with the bag.

6. The passive liquid recycle device of claim 3, wherein the guide pipe is located within the housing, and the outer pipe is at least partially located outside the housing.

7. The passive liquid recycle device of claim 1, wherein the housing has therein at least one first hanging portion, and the bag has at least one second hanging portion, wherein the second hanging portion is detachably connected to the corresponding first hanging portion.

8. The passive liquid recycle device of claim 7, wherein the first hanging portion is disposed on an inner side of a top surface of the housing, and the second hanging portion is disposed on a top end of the bag.

9. The passive liquid recycle device of claim 1. wherein the housing has a frame base and a plurality of door panels, and the plurality of door panels are openably coupled on different sides of the frame base.

10. The passive liquid recycle device of claim 1. wherein the housing has at least one pressure balance opening.
